(19) United States
(12) Patent Application Publication
(10) Pub. No.: US 2025/0273926 A1
(43) Pub. Date: Aug. 28, 2025

(54) PHOTOVOLTAIC CONVERSION DEVICE WITH ELECTROCALORIC ELEMENT

(71) Applicant: CLOUD LIGHT TECHNOLOGY LIMITED, Hong Kong (HK)

(72) Inventors: CHENG-KAI HUANG, New Taipei City (TW); MING-HSING CHUNG, New Taipei City (TW); CHANG-HUNG TIEN, New Taipei City (TW)

(21) Appl. No.: 18/587,985

(22) Filed: Feb. 27, 2024

(51) Int. Cl. H01S 5/024; H01S 5/02251; H01S 5/02253; H10N 10/13

(52) U.S. Cl. CPC H01S 5/02415; H01S 5/02251; H01S 5/02253; H01S 5/02453; H10N 10/13

(57) ABSTRACT

An electrocaloric photovoltaic conversion device having an electrocaloric device includes an electrocaloric device, a protective base, and a photovoltaic conversion module. The electrocaloric device includes a cooling plate, a heating plate having an area greater than an area of the cooling plate, and a diode array disposed between the cooling plate and the heating plate. The protective base surrounds the cooling plate to envelop the diode array. The photovoltaic conversion module is disposed in the protective base, and passes through the base to be in direct contact with the cooling plate. The electrocaloric photovoltaic conversion device having an electrocaloric device improves and reduces an overall element size while achieving package protection of the diode array of the electrocaloric device.

### BACKGROUND OF THE INVENTION

### 1. Field of the Invention

The present disclosure relates to an electrocaloric photovoltaic conversion device, and in particular to an electrocaloric photovoltaic conversion device having an electrocaloric device.

### 2. Description of the Related Art

Optical fibers have a low energy loss rate for electrical signals transmitted over cables, and so optical fiber communication is extensively applied in the field of communications. As shown in an electrocaloric photovoltaic conversion device 200 of the prior art in FIG. 1, a photovoltaic conversion module 8 usually converts an electrical signal into an optical signal by using a light emitting component 81 provided on a secondary adhesive base 82, and the optical signal is focused by a lens 83 and then sent toward an end of an optical fiber 84. The optical signal is transmitted to the other end via the optical fiber 84, emitted and focused from the optical fiber toward the other lens, received by an optical signal receiving element, and then converted into an electrical signal.

The light emitting component 81 generates a great amount of heat during operation, and thus there is a need to design a corresponding cooling mechanism. In one method, a cooling plate of an electrocaloric device 9 is adhered to a base 85 of the photovoltaic conversion module 8, and heat energy of the light emitting component 81 is absorbed by the cooling plate, while the other side (a heating plate) of the electrocaloric device 9 is away from the photovoltaic conversion module 8 and dissipates the heat energy outward. The configuration above faces certain issues that, a diode array in the middle of the electrocaloric device 9 is in an exposed state and this likely causes characteristic anomalies in a high-moisture environment. Thus, in addition to a limitation with respect to an application environment, an additional package protection is required, resulting in miniaturization difficulties of the entire element.

### BRIEF SUMMARY OF THE INVENTION

Therefore, to overcome the various issue of a conventional electrocaloric photovoltaic conversion device, the present disclosure provides an electrocaloric photovoltaic conversion device having an electrocaloric device capable of protecting a diode array of the electrocaloric device as well as achieving element miniaturization.

To achieve the above and other objects, the present disclosure provides an electrocaloric photovoltaic conversion device having an electrocaloric device, including: an electrocaloric device, including a cooling plate, a heating plate, and a diode array, wherein an area of the cooling plate is smaller than an area of the heating plate, and the diode array is disposed between the cooling plate and the heating plate; a protective base, surrounding the cooling plate to envelop the diode array; and a photovoltaic conversion module, disposed in the protective base, the photovoltaic conversion module passing through the base to be in direct contact with the cooling plate.

In an embodiment of the present disclosure, the protective base is disposed on the heating plate.

In an embodiment of the present disclosure, the photovoltaic conversion module includes a light emitting component, a secondary adhesive base, a lens, and an optical fiber. The secondary adhesive base is in direct contact with the cooling plate. The light emitting component and the lens are disposed at the secondary adhesive base. The optical fiber is located at a focus of the lens.

In an embodiment of the present disclosure, the electrocaloric photovoltaic conversion device having an electrocaloric device further includes a circuit board, which is electrically connected to the electrocaloric device and the light emitting component.

In an embodiment of the present disclosure, the electrocaloric photovoltaic conversion device having an electrocaloric device further includes a cover, which covers the photovoltaic conversion module and the protective base.

Thus, the electrocaloric photovoltaic conversion device having an electrocaloric device of the present disclosure improves and reduces an overall element size while achieving package protection of the diode array of the electrocaloric device, and further mitigates the issue of needing a production process of secondary packaging as in the prior art and reduces the possibility of thermal cycling caused by such secondary packaging.

### BRIEF DESCRIPTION OF THE DRAWINGS

FIG. 1 is a schematic diagram of an electrocaloric photovoltaic conversion device of the prior art.

FIG. 2 is a perspective schematic diagram of an electrocaloric photovoltaic conversion device having an electrocaloric device according to an embodiment of the present disclosure.

FIG. 3 is an exploded diagram of an electrocaloric photovoltaic conversion device having an electrocaloric device according to an embodiment of the present disclosure.

### DETAILED DESCRIPTION OF THE INVENTION

To fully understand the present invention, the present disclosure is described in detail by way of specific embodiments with reference to the accompanying drawings. A person skilled in the art would be able to understand the objects, features, and effects of the present disclosure on the basis of the disclosure of the present application. It should be noted that, the present disclosure may be implemented or applied by other specific embodiments, and changes and modifications may also be made on the basis of different perspectives and applications to various details in the description without departing from the spirit of the present disclosure. Technical contents associated with the present disclosure are described in detail below, and it should be noted that the disclosure is not to be construed as limitations to the scope of claims of the present disclosure. Associated details are provided in the description below.

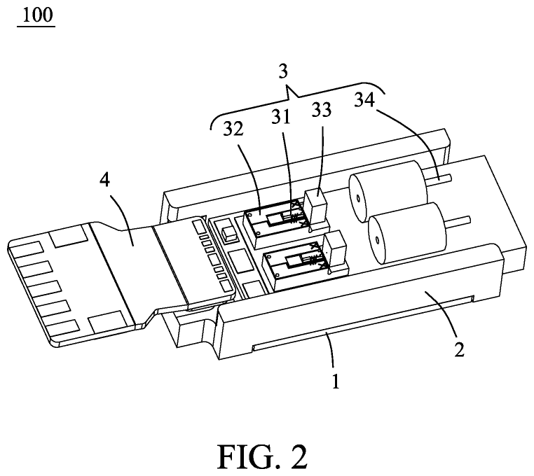

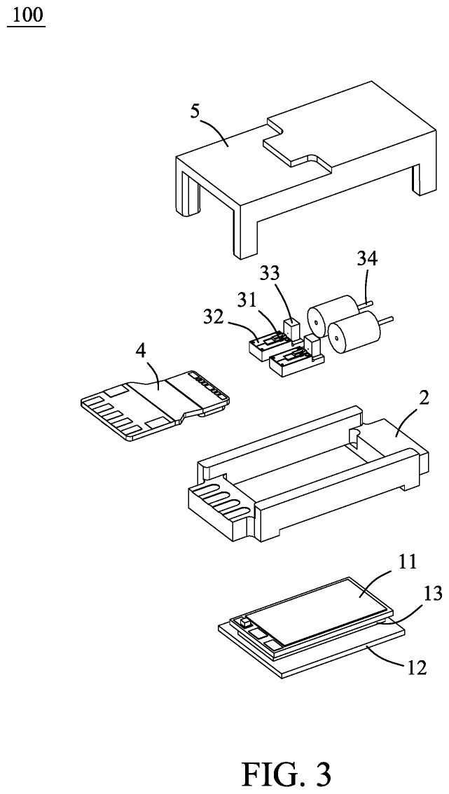

As shown in FIG. 2 and FIG. 3, an electrocaloric photovoltaic conversion device 100 having an electrocaloric device according to an embodiment of the present disclosure includes an electrocaloric device 1, a protective base 2 and a photovoltaic conversion module 3.

The electrocaloric device 1 is, for example, a thermo-electric chip (TEC), and is an element for heating and cooling by means of passing an electric current based on the Peltier effect. The electrocaloric device 1 includes a cooling plate 11, a heating plate 12, and a diode array 13. The cooling plate 11 is a cold end, the heating plate 12 is a hot end, and the diode array 13 is disposed between the cooling plate 11 and the heating plate 12. An area of the cooling plate 11 is smaller than an area of the heating plate 12, such that the cooling plate 11 and the heating plate 12 are formed to have a substantially stepped shape.

A protective base 2 surrounds the cooling plate 11 to envelop the diode array 13, such that the diode array 13 is covered and protected by the protective base 2. In an embodiment, the protective base 2 is disposed on a surface of the heating plate 12 facing the cooling plate 11. Thus, in addition to reducing a thickness of the overall device, an occupied footprint can also be lowered.

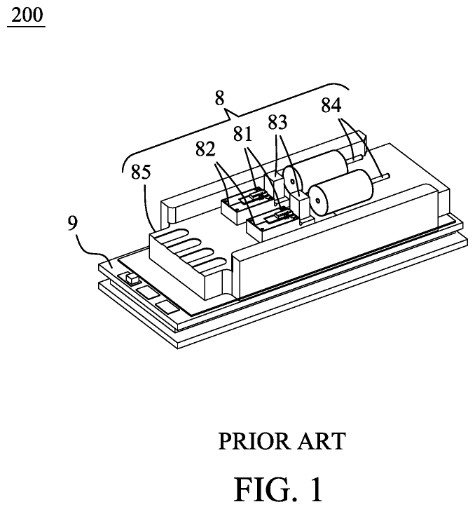

The photovoltaic conversion module 3 is disposed in the protective base 2. In contrast to the photovoltaic conversion module 8 of the prior art in FIG. 1 that needs to be indirectly adhered to the cooling plate of the electrocaloric device 9 via the base 85, the photovoltaic conversion module 3 of the present disclosure passes through the base 2 and is in direct contact with the cooling plate 11, thus reducing the thickness of the overall device as well as enhancing cooling efficiency.

In conclusion, an electrocaloric photovoltaic conversion device 100 having an electrocaloric device of the present disclosure improves and reduces an overall element size while achieving package protection of the diode array 13 of the electrocaloric device 1, and further mitigates the issue of needing a secondary packaging production process as in the prior art and reduces the possibility of thermal cycling caused by such secondary packaging.

Further, in an embodiment, as shown in FIG. 2 and FIG. 3, the photovoltaic conversion module 3 is, for example, a light emitting module, and includes a light emitting component 31, a secondary adhesive base 32, a lens 33, and an optical fiber 34. The light emitting component 31 is, for example, a laser element, and converts an input electrical signal into an optical signal and emits the optical signal toward an end of the optical fiber 34. The secondary adhesive base 32 is in direct contact with the cooling plate 11, and is preferably made of silicon-based material by a semiconductor manufacturing process, so as to reduce manufacturing errors. The light emitting component 31 and the lens 33 are disposed at the secondary adhesive base 32, the light emitting component 31 matches a center of the lens 33, and the optical fiber 34 is located at a focus of the lens 33. Since the light emitting module generates high-temperature heat energy, the electrocaloric device 1 is preferably applied to the light emitting module. However, the present disclosure is not limited to the example above. In other embodiments, the photovoltaic conversion module 3 can also be a light receiving module which includes a photodiode, receives an optical signal emitted from an optical fiber and converts the optical signal into an electrical signal.

Further, in an embodiment, the electrocaloric photovoltaic conversion device 100 having an electrocaloric device of the present disclosure further includes a circuit board 4, which is electrically connected to the electrocaloric device 1 and the light emitting component 31. The circuit board 4 can supply electric energy needed by the electrocaloric device 1 and transmit the electric energy to the light emitting component 31.

Further, in an embodiment, as shown in FIG. 3, the electrocaloric photovoltaic conversion device 100 having an electrocaloric device of the present disclosure further includes a cover 5, which covers the photovoltaic conversion module 3 and the protective base 2.

The present invention is described by way of the embodiments above. A person skilled in the art should understand that, these embodiments are merely for illustrating the present invention and are not to be construed as limitations to the scope of the present invention. It should be noted that all equivalent changes, replacements and substitutions made to the embodiments are encompassed within the scope of the present invention. Therefore, the scope of legal protection of the present invention should be defined by the appended claims.

What is claimed is:

1. An electrocaloric photovoltaic conversion device having an electrocaloric device, comprising:
an electrocaloric device, comprising a cooling plate, a heating plate, and a diode array, wherein an area of the cooling plate is smaller than an area of the heating plate, and the diode array is disposed between the cooling plate and the heating plate;
a protective base, surrounding the cooling plate to envelop the diode array; and
a photovoltaic conversion module, disposed in the protective base, the photovoltaic conversion module passing through the protective base to be in direct contact with the cooling plate.

2. The electrocaloric photovoltaic conversion device according to claim 1, wherein the protective base is disposed on the heating plate.

3. The electrocaloric photovoltaic conversion device according to claim 1, wherein the photovoltaic conversion module comprises a light emitting component, a secondary adhesive base, a lens, and an optical fiber, the secondary adhesive base is in direct contact with the cooling plate, the light emitting component and the lens are disposed at the secondary adhesive base, and the optical fiber is located at a focus of the lens.

4. The electrocaloric photovoltaic conversion device according to claim 3, further comprising a circuit board electrically connected to the electrocaloric device and the light emitting component.

5. The electrocaloric photovoltaic conversion device according to claim 1, further comprising a cover covering the photovoltaic conversion module and the protective base.
